(19) United States
(12) Patent Application Publication
(10) Pub. No.: US 2009/0047808 A1
(43) Pub. Date: Feb. 19, 2009

(54) Electrical connector

(75) Inventor: Hao-Yun Ma, Tu-cheng (TW)

Correspondence Address: WEI TE CHUNG;FOXCONN INTERNATIONAL, INC., 1650 MEMOREX DRIVE, SANTA CLARA, CA, 95050, US

(73) Assignee: HON HAI PRECISION IND. CO., LTD.

(21) Appl. No.: 12/229,011

(22) Filed: Aug. 18, 2008

(30) Foreign Application Priority Data
Aug. 17, 2007 (CN) 200720042945.5

(51) Int. Cl. H05K 1/00

(52) U.S. Cl. 439/68

(57) ABSTRACT

The present invention provides an electrical connector for electrical connecting an IC package having a plurality of pins to a PCB. The electrical connector comprises a base defining a plurality of passageways, a plurality of contacts received in the passageways, and a cover moveable relative to the base from a first position to a second position. The cover defines a plurality of through holes corresponding the passageway. The contacts each have a contacting portion disposed in the through hole. When the cover is at the first position, the pins of the con IC package do not contact with the contacting portions of the contacts; and when the cover is at the second position, the pins contact with the contacting portions in the through holes of the cove.

### BACKGROUND OF THE INVENTION

1. Field of the Invention

The present invention relates to the art of electrical connectors. In detail, the present invention relates to a central processing unit (CPU) electrical connector/socket.

2. Background of the Invention

CPU sockets are widely used for establishing electrical connection between CPU and a printed circuit board (PCB)/motherboard. Therefore, CPU sockets are mounted on motherboards and hold CPUs execution of programs. Several types of CPU sockets are available with different structures. For example, type of Pin Grid Array (PGA) socket, which is found in U.S. Pat. No. 6,663,409 issued to Liao on Dec. 16, 2003.

A PGA socket generally comprises a base, a moveable cover mounted on the base, an actuator arranged between the base and the cover and a plurality of contacts received in the base. The base defines a plurality of passageways and the cover defines a plurality of through holes corresponding to the passageways. When the PGA socket connects the CPU to the PCB, the CPU is disposed upon the cover with its pins inserted into the through holes of the cover and the passageways of the base. The pins will contact with the contacts after a movement of the cover under a force from the actuator.

Because the pins of the IC pass through the through holes of the cover for positioning the IC, it is important to ensure proper positioning. Moreover, while such a connector is in use, improper position of the IC pins damage the contacts. As a result, the reliability of the electrical connection may be affected. Moreover, the passageway generally requires a large space for allowing the pins inserted into.

In view of foregoing, a new electrical connector is needed to overcome the above-mentioned shortcomings.

### SUMMARY OF THE INVENTION

Accordingly, an object of the present invention is to provide an electrical connector that can provides reliable electrical connection between the contacts and the pins of the CPU.

To achieve the above-mentioned object, in a preferred embodiment of the present invention, the present invention provides an electrical connector for electrical connecting an IC package having a plurality of pins to a PCB. The electrical connector comprises a base defining a plurality of passageways, a plurality of contacts received in the passageways, and a cover moveable relative to the base from a first position to a second position. The cover defines a plurality of through holes corresponding the passageway. The contacts each have a contacting portion disposed in the through hole. When the cover is at the first position, the pins of the con IC package do not contact with the contacting portions of the contacts; and when the cover is at the second position, the pins contact with the contacting portions in the through holes of the cove.

Other objects, advantages and novel features of the present invention will become more apparent from the following detailed description when taken in conjunction with the accompanying drawings.

### BRIEF DESCRIPTION OF THE DRAFLANGES

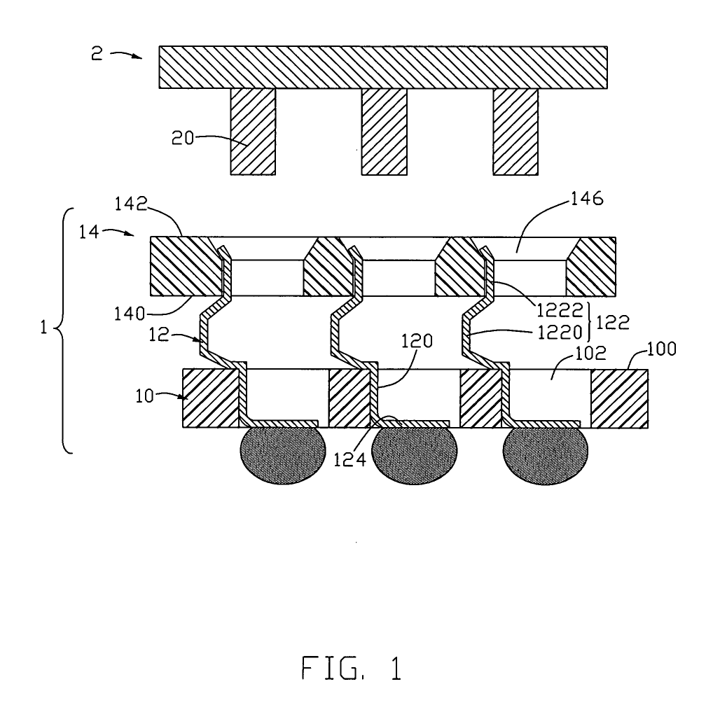

FIG. 1 is an exploded, sketch view of an electrical connector system in accordance with a preferred embodiment of the present invention, wherein the IC package is ready to be mounted on the electrical connector;

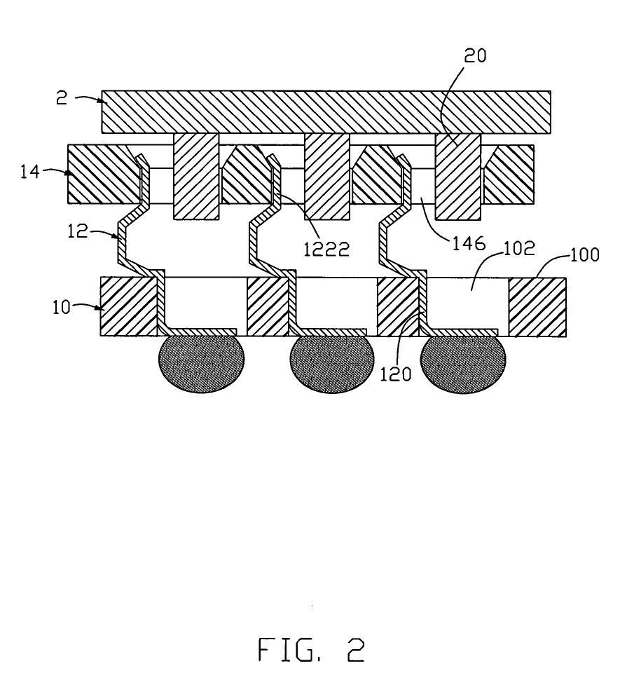

FIG. 2 is a sketch view of the electrical connector system; the IC package being mounted upon the cover without pushed toward the base; and

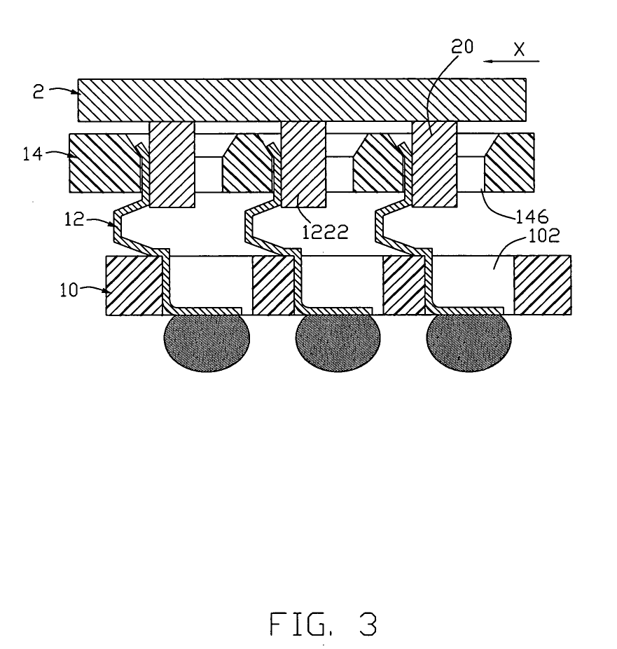

FIG.3 is a sketch view of the electrical connector system, and the IC package is pushed toward the base and contacting with the contact after a sliding movement elative to the cover.

### DETAILED DESCRIPTION OF THE PREFERRED EMBODIMENT OF THE INVENTION

Reference will now be made to accompany drawings to describe the present invention in detail.

Referring to FIGS. 1-3, according to a preferred embodiment of the present invention, an electrical connector 1 used for establishing electrical connection between an IC package 2 (e.g. CPU) and a PCB (not shown) is shown.

The electrical connector 1 comprises base 10, a plurality of contacts 12 received in the base 10, and a cover 14. The base 10 has a mating surface 100 with a plurality of passageways 102.

The cover 14 is moveably mounted upon the base 10, defining a bottom surface 140 corresponding to the mating surface 100 of the base 10 and an upper surface 142 opposite to the bottom surface 140. A plurality of through holes 146 extends through both the upper surface 142 and the bottom surface 140. Each of the plurality of through holes 146 is configured to ensure a pin 20 of the IC package 2 to be inserted into. The plurality of through holes 146 each define a guiding slot (not labeled), which is formed by a chamfer arranged at a position near the upper surface 142.

Each of the plurality of contacts 12 is received in a passageway 102, and has a base portion 120 for securing the contact 12 in the passageway 102, a resilient arm 122 extending from an upper end of the base portion 120 and a soldering portion 124 extending from a lower end of the base portion 120. The resilient arm 122 comprises a connecting portion 1220 extending from the upper end of the base portion 120, a contacting portion 1222 extending from a free end of the connecting portion 1220. The contacting portion 1222 is predisposed in the through hole 146 of the cover 14. The contacting portion 1222 is adjacent to a predetermined area of inner wall of the through hole 146 and a space ensuring the pin 20 of the package 2 to be inserted into is defined between the contacting portion 1222 and other portion of the inner wall of the through hole 146. The base portion 120 and the contacting portion 1222 are located at the same side of the connecting portion 1220. The connecting portion 1220 is offset relative to the through hole 146 of the cover 14 and located between the base 10 and the cover 14.

It is needed to point out; an actuator (not shown) will be arranged between the base 10 and the cover 14. As a conventional PGA socket, the actuator may be an eccentric cam or an operating lever. The actuator is used for driving the cover 14 to slide relative to the base 10 from a first position to a second position, which is well know to a people having ordinary skill in the art.

The IC package 2 is mounted upon the upper surface 142 of the cover and has a plurality of pins 20 corresponding to the through holes 146.

Referring to the FIGS. 2-3, a process of establishes electrical connection between the IC package 2 between the electrical connector 1 is shown. Referring to FIG. 2, the cover 14 is at the first position; pins 20 of IC package 2 being inserted into the through holes 146 of the cover 14. At this time, the pins 20 do not contact with any contacts 12. Referring to FIG. 3, while the cover 14 is at the second position after a sliding along an X direction, the pins 20 are contacting with the contacts 12.

According to the preferred embodiment of the present invention, the pins 20 of the IC package 2 contact with the contacting portion 1222 of the contact 12 in space of the through hole 146 of the cover. The pins 20 do not need to be inserted into the passageway 102. Thus, the contacts 12 do not need a large cavity arranged in the passageway 102. Thereby, electrical connection between the pins 20 of the IC package 20 and the contacts 12 can be conveniently and accurately established.

Although the present invention has been described with reference to the accompanying drawings, it is not to be construed as being limited thereto. Various alterations and modifications can be made to the embodiments without in any way departing from the scope or spirit of the present invention as defined in the appended claims. Such modifications and alterations that may be apparent to a person skilled in the art are intended to be included within the scope of this invention as defined in by the accompanying claims.

What is claimed is:

1. An electrical connector for electrical connecting an IC package having a plurality of pins to a PCB, comprising:
a base defining a plurality of passageways;
a plurality of contacts received in the passageways; and
a cover moveable relative to the base from a first position to a second position, the cover defining a plurality of through holes corresponding to the plurality of contacts;
each contact having a contacting portion disposed in the through hole of the cover, the contacting portion of each contact and the base defining an inserted space therebetween; wherein
when the cover is at the first position, the pins of the IC package do not contact with the contacting portions of the contacts; and when the cover is at the second position, the pins will contact with the contacting portions in the through holes of the cover.

2. The electrical connector as claimed in claim 1, the contact further comprising a base portion, a resilient arm extending from an upper end of the base portion, and a soldering portion extending from a lower end of the base portion, wherein the contacting portion is disposed on the resilient arm.

3. The electrical connector as claimed in claim 2, the resilient arm comprising a connecting arm extending from the upper end of the base portion, wherein the contacting portion is disposed on an end of the connecting portion.

4. An electrical connector for electrically mating with an IC package having a plurality of pins, comprising:
a base defining a plurality of passageways;
a plurality of contacts received in the passageways; and
a cover moveable relative to the base from a first position to a second position, the cover defining a plurality of through holes corresponding to the plurality of passageways, respectively;
each contact having a contacting portion disposed in the through hole of the cover, each contacting portion of the contacts and the base defining an inserted space therebetween for receiving the pin of the IC package.

5. The electrical connector as claimed in claim 5, wherein each pin of the IC package is facing to the contacting portion of the contact at one side thereof and facing to an inner wall of the through hole at the other side.

6. The electrical connector as claimed in claim 5, wherein each contact further comprising a soldering portion at a lower end thereof, a base portion extending upwardly from the soldering portion, and a connecting portion located between the base portion and the contacting portion.

7. The electrical connector as claimed in claim 6, wherein the base portion and the contacting portion are located at the same side of the connecting portion.

8. The electrical connector as claimed in claim 7, wherein the connecting portion is offset relative to the through hole of the cover and located between the base and the cover.

9. An electrical connector assembly comprising:
an insulative base with a plurality of contacts disposed therein;
an insulative cover positioned above the base with a space therebetween in a vertical distance;
a plurality of through holes formed in the cover an in alignment with the corresponding contacts, respectively;
each of said contacts including a deflectable arm extending above the base toward the cover and essentially in said space; and
an electronic package positioned upon the cover with a plurality of conductive pins each downwardly extending through the through holes to contact a contacting end of the deflectable arm of the corresponding contact when said electronic package is moved from a position to a second position along a front-to-back direction.

10. The electrical connector assembly as claimed in claim 9, wherein the deflectable arm extends offset from a main body of the corresponding contact is the base.

11. The electrical connector assembly as claimed in claim 9, wherein said contacting end is located in the corresponding through hole of the cover.

12. The electrical connector assembly as claimed in claim 9, wherein said electronic package is moved along with the cover in said front-to-back direction.
